(19) United States
(12) Patent Application Publication
(10) Pub. No.: US 2012/0115281 A1
(43) Pub. Date: May 10, 2012

(54) METHOD OF MANUFACTURING SEMICONDUCTOR DEVICE

(75) Inventors: Tomohito Iwashige, Ibaraki-shi (JP); Tomoaki Ichikawa, Ibaraki-shi (JP); Naoya Sugimoto, Ibaraki-shi (JP); Mitsuaki Fusumada, Ibaraki-shi (JP); Hiroyuki Hotehama, Ibaraki-shi (JP); Shinya Akizuki, Ibaraki-shi (JP)

(73) Assignee: NITTO DENKO CORPORATION, Osaka (JP)

(21) Appl. No.: 13/289,472

(22) Filed: Nov. 4, 2011

(30) Foreign Application Priority Data
Nov. 10, 2010 (JP) 2010-252315

(51) Int. Cl. H01L 21/56

(52) U.S. Cl. 438/127; 257/E21.502

(57) ABSTRACT

A method of manufacturing a semiconductor device which is excellent in high-temperature high-humidity reliability without decreasing moldability and curability is provided. The method includes sealing a semiconductor element in resin using a semiconductor-sealing epoxy resin composition; and then performing a heating treatment. The semiconductor-sealing epoxy resin composition contains (A) an epoxy resin of formula (1):

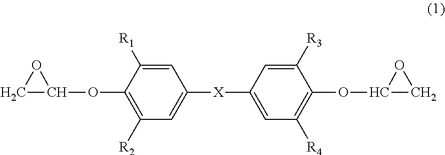

wherein X is a single bond, —CH₂—, —S— or —O—; and R₁ to R₄, which may be the same as or different, are each —H or —CH₃, (B) a phenolic resin, (C) an amine-based curing accelerator, and (D) an inorganic filler. The heating treatment is performed under heat treatment conditions defined by a region in which a relationship t≧3.3×10⁻⁵ exp(2871/T) is satisfied where t is heat treatment time in minutes and T is heat treatment temperature in ° C. and where 185≦T≦300.

### BACKGROUND OF THE INVENTION

1. Field of the Invention

The present invention relates to a method of manufacturing a semiconductor device which is excellent in moldability, curability and high-temperature high-humidity reliability.

2. Description of the Related Art

Conventionally, a semiconductor element such as a transistor, an IC and an LSI circuit is resin-sealed in a plastic package, e.g. an epoxy resin composition, from the viewpoints of protecting the semiconductor element from external environments and allowing the handling of the semiconductor element, thereby providing a semiconductor device.

In general, a curing accelerator is mixed in the aforementioned epoxy resin composition for the purpose of accelerating the curing reaction of resin during molding. Examples of the curing accelerator used conventionally include amines, imidazole compounds, nitrogen-containing heterocyclic compounds such as 1,8-diazabicyclo[5.4.0]undecene-7, phosphine compounds, quaternary ammonium compounds, phosphonium compounds, and arsonium compounds.

An epoxy resin composition containing such curing accelerators is generally formulated to cause the reaction to occur rapidly under high-temperature conditions during the molding, thereby completing the curing within a short time. For this reason, there are cases where the curing reaction starts before the epoxy resin composition is fully charged in a mold during the molding. These circumstances give rise to the increase in viscosity of resin and the decrease in fluidity thereof, which might cause troubles including deformation of bonding wires connecting a semiconductor element and external terminals such as lead frames, contact between adjacent bonding wires, and a break in the bonding wires, and further cause a trouble such that the mold is not sufficiently filled with the resin, and a more significant trouble in moldability.

To avoid such troubles, there has been proposed a method which uses, for example, a microcapsule type curing accelerator to delay the start of the curing reaction, as disclosed in Japanese Published Patent Application No. 10-168164 (1998).

However, the aforementioned method presents problems such that productivity is lowered significantly because the curing reaction proceeds slowly and such that the hardness and strength of the cured material itself become insufficient. For these reasons, a method which uses an imidazole compound as the curing accelerator to obtain good curability and good fluidity has been proposed to take the curability problem as mentioned above into consideration and to avoid the moldability trouble. Such a method is disclosed in Japanese Published Patent Application No. 2005-162943.

Another important characteristic required for semiconductor-sealing resin is high-temperature high-humidity reliability. Under high-temperature or high-humidity conditions, corrosion of aluminum interconnect lines on a semiconductor element is liable to proceed, because ionic impurities such as chlorine ions contained in epoxy resin migrate easily. Thus, conventional semiconductor-sealing epoxy resin compositions have a drawback in high-temperature high-humidity reliability. The ionic impurities such as chlorine ions contained in the epoxy resin which cause the poor high-temperature high-humidity reliability result from glycidyl etherification of phenols caused by epihalohydrin in the process steps of manufacturing the epoxy resin. Conventional cresol novolac type epoxy resins which have a high degree of solubility in a solvent can be rinsed with water, whereby epoxy resins of low chlorine content (of high purity) are obtained. However, a low-viscosity crystalline epoxy resin used for highly filling an inorganic filler which is one of the compounding ingredients has a low degree of solubility in a solvent, whereby it is difficult to obtain an epoxy resin of high purity, as disclosed in Japanese Published Patent Application No. 2-187420 (1990).

In view of the foregoing, some methods for trapping anionic impurities by the use of ion-trapping agents containing Bi-based inorganic compounds and hydrotalcite compounds have been proposed to trap ionic impurities included in the semiconductor-sealing epoxy resin compositions which might cause the poor high-temperature high-humidity reliability, as disclosed in Japanese Published Patent Applications Nos. 11-240937 (1999), 9-157497 (1997), and 9-169830 (1997). Even when these methods are used, however, it has been difficult to produce the sufficiently satisfactory effect of improving the high-temperature high-humidity reliability. Also, the increase in the viscosity of the epoxy resin compositions has decreased the fluidity to consequently exert adverse effects on moldability.

### SUMMARY OF THE INVENTION

A method is provided of manufacturing a semiconductor device which is excellent in high-temperature high-humidity reliability without decreasing moldability and curability.

A method of manufacturing a semiconductor device comprises the steps of: (a) sealing a semiconductor element in resin using a semiconductor-sealing epoxy resin composition; and (b) performing a heating treatment after the step (a). The semiconductor-sealing epoxy resin composition contains (A) an epoxy resin represented by the following general formula (1):

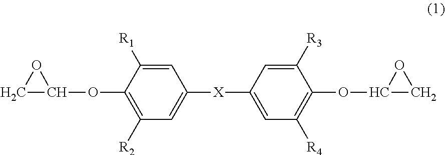

wherein X is a single bond, —CH₂—, —S— or —O—; and R₁ to R₄, which may be the same as or different from each other, are each —H or —CH₃, (B) a phenolic resin, (C) an amine-based curing accelerator, and (D) an inorganic filler. The heating treatment in the step (b) is performed under the following conditions: (x) heat treatment conditions defined by a region in which a relationship t≧3.3×10⁻⁵ exp (2871/T) is satisfied where t is heat treatment time in minutes and T is heat treatment temperature in ° C. and where 185≦T≦300.

A semiconductor device has been obtained which is excellent in high-temperature high-humidity reliability in which good moldability and curability are imparted to an epoxy resin composition serving as a sealing material because of the occurrence of a proper curing reaction and in which the occurrence of, for example, gold wire sweep is suppressed. Attention has been directed towards compounding ingredients serving as the sealing material and also conditions for the manufacture of a semiconductor device in addition to the sealing material. The high-temperature high-humidity reliability as well as the moldability and the curability is improved when resin sealing is done using a sealing material containing the specific biphenyl type epoxy resin as an epoxy resin and the amine-based curing accelerator as a curing accelerator and when heating treatment is performed after the resin sealing. A relationship between heating time and heating temperature which produces excellent effects has been studied. When the sealing material using the aforementioned specific components is used and the heating treatment is performed under the aforementioned conditions (x), excellent moldability and curability are achieved, and a semiconductor device excellent in high-temperature high-humidity reliability is provided.

The method of manufacturing a semiconductor device comprises: sealing a semiconductor element in resin using a semiconductor-sealing epoxy resin composition containing the aforementioned components (A) to (D); and performing a heating treatment after the step of resin sealing. The heating treatment is performed under the conditions (x). This provides a semiconductor device excellent in high-temperature high-humidity reliability without decreasing moldability and curability.

Preferably, the amine-based curing accelerator (the component (C)) is an imidazole compound represented by the general formula (2) to be described below. In this case, the moldability including fluidity and the like, and the curability are further improved.

### BRIEF DESCRIPTION OF THE DRAWINGS

FIG. 1 is a graph showing a relationship between heat treatment time (plotted along the ordinate) and heat treatment temperature (plotted along the abscissa) which are conditions for a heating treatment process step in a method of manufacturing a semiconductor device.

FIG. 2 is a plan view schematically showing a semiconductor device for use in measurement for gold wire sweep evaluation.

FIG. 3 is a view for schematically illustrating a method of measuring the amount of gold wire sweep.

### DETAILED DESCRIPTION OF THE INVENTION

A semiconductor-sealing epoxy resin composition is provided using a specific epoxy resin (component A), a phenolic resin (component B), an amine-based curing accelerator (component C), and an inorganic filler (component D). The semiconductor-sealing epoxy resin composition is generally provided as a sealing material in liquid form, in powder form, in the form of tablets prepared by the tablet compression of the powder, or in sheet form.

The specific epoxy resin (component A) is an epoxy resin represented by the following general formula (1):

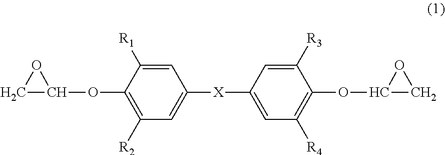

wherein X is a single bond, —CH₂—, —S— or —O—; and R₁ to R₄, which may be the same as or different from each other, are each —H or —CH₃.

In particular, an epoxy resin represented by the aforementioned general formula (1) wherein X is a single bond and R₁ to R₄ are all —CH₃ is preferably used from the viewpoint of moldability including fluidity and the like.

It is preferable that an epoxy resin component is comprised of only the aforementioned specific epoxy resin (component A). However, other epoxy resins may be used in combination with the specific epoxy resin (component A). Examples of the aforementioned other epoxy resins include bisphenol A epoxy resins, phenolic novolac epoxy resins, cresol novolac epoxy resins, and triphenylmethane epoxy resins. These are used either singly or in combination. These epoxy resins having an epoxy equivalent of 150 to 250 including the component A and a softening point or a melting point of 50 to 130° C. is preferably used. When the aforementioned other epoxy resins are used in combination with the specific epoxy resin (component A), the proportion thereof is not particularly limited so far as the effects are not impaired. It is, however, preferable that the proportion of the aforementioned other epoxy resins is specifically not greater than 30% by weight, based on the total weight of the epoxy resin component.

The phenolic resin (component B) for use with the aforementioned epoxy resin (component A) functions as a curing agent for the epoxy resin (component A), and refers to monomers, oligomers and polymers in general which have two or more phenolic hydroxyl groups per molecule. Examples of the phenolic resin (component B) include phenolic novolac, cresol novolac, biphenyl novolac, triphenylmethane type, naphthol novolac, xylylene novolac, phenol aralkyl resins, and biphenyl aralkyl resins. These are used either singly or in combination. In particular, phenol aralkyl resins and biphenyl aralkyl resins which are low in moisture absorbency are preferably used from the viewpoints of moldability and reliability.

The epoxy resin (component A) and the phenolic resin (component B) are mixed preferably in a ratio of 0.5 to 2.0 equivalents, more preferably in a ratio of 0.8 to 1.2 equivalents, of hydroxyl groups in the phenolic resin to one equivalent of epoxide groups in the epoxy resin.

Examples of the amine-based curing accelerator (component C) for use with the components A and B include imidazoles such as 2-methylimidazole, tertiary amines such as triethanolamine and 1,8-diazabicyclo[5.4.0]undecene-7, and 2,4-diamino-6-[2′-undecyl imidazolyl-(1′)]-ethyl-s-triazine. Of these amine-based curing accelerators, an imidazole compound represented by the following general formula (2) is preferably used from the viewpoints of moldability including fluidity and the like, and curability.

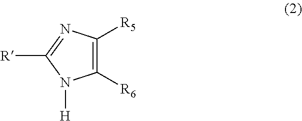

wherein R′ is an alkyl group or an aryl group; and R₅ and R₆, which may be the same as or different from each other, are each —CH₃ or —CH₂OH, and at least one of R₅ and R₆ is —CH₂OH.

In the formula (2), R′ is an alkyl group or an aryl group. Specific examples of the alkyl group include alkyl groups having a carbon number ranging from 1 to 6. Specific examples of the aryl group include phenyl groups and p-tolyl groups. Specific examples of the imidazole compound represented by the general formula (2) include 2-phenyl-4-methyl-5-hydroxyimidazole, and 2-phenyl-4,5-dihydroxymethylimidazole.

The imidazole compound represented by the general formula (2) is produced, for example, in a manner to be described below. Specifically, 2-substituted imidazoles and formaldehyde are caused to react in the presence of an alkali, whereby the imidazole compound is produced.

The content of the amine-based curing accelerator (component C) is preferably in the range of 1 to 20 parts by weight, more preferably in the range of 2 to 10 parts by weight, per 100 parts by weight of the phenolic resin (component B). When the content of the amine-based curing accelerator (component C) is too low, the intended curing reaction of the epoxy resin (component A) and the phenolic resin (component B) is less likely to proceed, so that it is difficult to attain a sufficient degree of curability. When the content of the amine-based curing accelerator (component C) is too high, on the other hand, the curing reaction proceeds too fast, so that there is a tendency to impair moldability.

Other curing accelerators may be used in combination with the amine-based curing accelerator (component C) so far as the characteristics are not impaired. Examples of the aforementioned other curing accelerators include triarylphosphines, and tetraphenylphosphonium tetraphenylborate. These are used either singly or in combination. When the aforementioned other curing accelerators are used in combination with the amine-based curing accelerator (component C), it is preferable that the content of the aforementioned other curing accelerators is specifically not greater than 50% by weight, based on the total weight of a curing accelerator component.

Examples of the inorganic filler (component D) for use with the components A to C include silica powders such as fused silica powders and crystalline silica powders, alumina powders, and talcs. These inorganic fillers used herein may be in crushed form, in spherical form or in ground or milled form. In particular, spherical fused silica powders are preferably used. These inorganic fillers are used either singly or in combination. The inorganic filler (component D) having an average particle diameter in the range of 5 to 40 μm is preferably used from the viewpoint of providing good fluidity. The average particle diameter of the inorganic filler (component D) may be measured, for example, with a laser diffract ion scattering particle size distribution measuring apparatus.

The content of the inorganic filler (component D) is preferably in the range of 70 to 95% by weight, particularly preferably in the range of 85 to 92 by weight, based on the total weight of the epoxy resin composition. When the content of the inorganic filler (component D) is too low, the viscosity of the epoxy resin composition becomes too low, so that poor appearance (voids) during the molding is prone to result. When the content of the inorganic filler (component D) is too high, on the other hand, fluidity decreases, so that wire sweep (wire deformation) and the insufficient filling of the mold are prone to result.

Other additives may be mixed in the semiconductor-sealing epoxy resin composition, as appropriate, in addition to the aforementioned components A to D. Examples of the additives include silane coupling agents, flame retardants, flame retardant assistants, mold release agents, ion-trapping agents, pigments and coloring agents such as carbon blacks, stress reducing agents, and tackifiers.

A variety of silane coupling agents may be used as the aforementioned silane coupling agents. In particular, silane coupling agents having two or more alkoxy groups are preferably used. Specific examples of such silane coupling agents include β-(3,4-epoxycyclohexyl)ethyltrimethoxysilane, γ-glycidoxypropyltrimethoxysilane, γ-mercaptopropyltrimethoxysilane, γ-(2-aminoethyl)aminopropyltrimethoxysilane, γ-mercaptopropylmethyldimethoxysilane, γ-anilinopropyltrimethoxysilane, and hexamethyldisilazane. These are used either singly or in combination.

Examples of the aforementioned flame retardants include novolac type brominated epoxy resins and metal hydroxides. Examples of the aforementioned flame retardant assistants include diantimony trioxide and antimony pentoxide. These are used either singly or in combination.

Examples of the aforementioned mold release agents include compounds of higher fatty acids, higher fatty acid esters, and higher fatty acid calcium. For example, carnauba waxes and polyethylene waxes are used. These are used either singly or in combination.

All compounds having an ion trapping ability may be used as the aforementioned ion-trapping agents. For example, compounds of hydrotalcites and bismuth hydroxide are used.

Examples of the aforementioned stress reducing agents include butadiene rubbers such as methyl acrylate-butadiene-styrene copolymers and methyl methacrylate-butadiene-styrene copolymers, and silicone compounds.

The semiconductor-sealing epoxy resin composition is produced, for example, in a manner to be described below. The aforementioned components A to D and other additives, as required, are prepared and mixed together. Thereafter, the mixture in heated condition is melt-mixed using a kneading machine such as a mixing mill, and is rolled in sheet form. Alternatively, the mixture is melt-mixed, and then cooled to room temperature. Thereafter, the cooled mixture is crushed using a known means, and is subjected to tablet compression, as required. The semiconductor-sealing epoxy resin composition is produced through such a series of process steps.

The sealing of a semiconductor element in resin using such a semiconductor-sealing epoxy resin composition is not particularly limited, but may be performed by a known molding method such as typical transfer molding.

A method of manufacturing a semiconductor device includes the step of heating treatment which is added after the aforementioned resin sealing, and is characterized by performing the heating treatment under the following conditions:

(x) heat treatment conditions defined by a region in which a relationship t≧3.3×10⁻⁵ exp(2871/T) is satisfied where t is heat treatment time in minutes and is heat treatment temperature in ° C. and where 185° C.≦heat treatment temperature T° C.≦300° C.

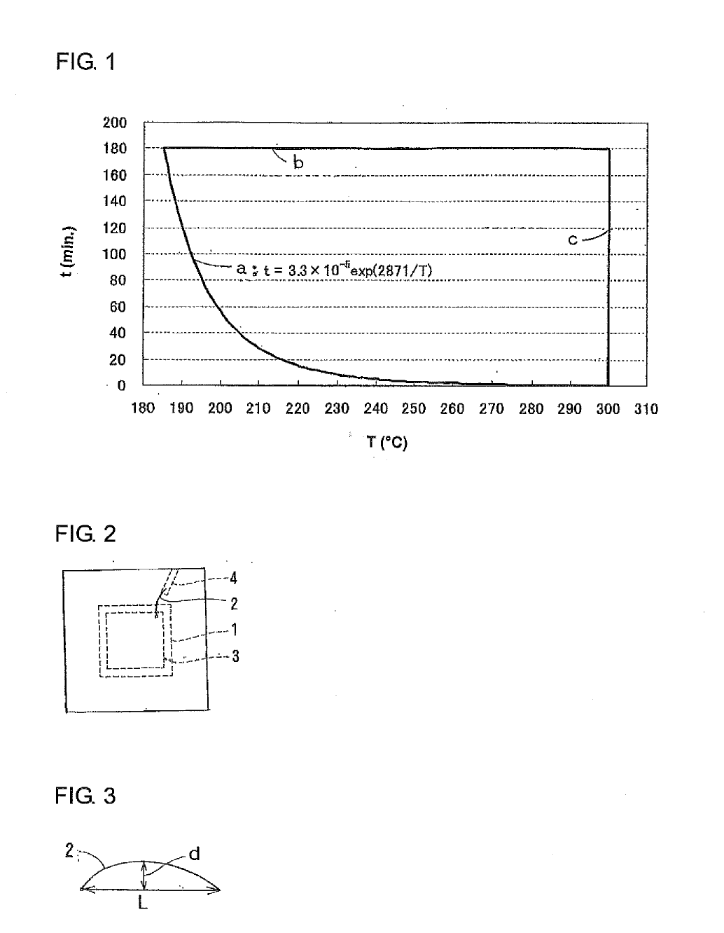

In the aforementioned heating treatment, the time required for heat treatment, that is, the heat treatment time (t in minutes) differs and varies in accordance with the heat treatment temperature (T in ° C.) in this manner. FIG. 1 shows a relationship between the heat treatment time and the heat treatment temperature under the aforementioned conditions (x). In FIG. 1, the curve a represents t=3.3×10−5 exp(2871/T). The conditions (x) denote a region having values (t in minutes) inclusive of and greater than the curve a. In consideration for productivity and heat resistance of a semiconductor element in practical terms, heat treatment time equaling 180 minutes represented by the line b shown in FIG. 1 shall be the common upper limit of the heat treatment time (t in minutes), and heat treatment temperature T (° C.) equaling 300° C. represented by the line c shown in FIG. 1 shall be the upper limit of the heat treatment temperature (T in ° C.).

The upper limit of the heat treatment time (t in minutes) represented by the line b is determined as 180 minutes because heat treatment for 180 minutes or longer is impractical in consideration for productivity. The practical upper limit of the heat treatment temperature (T in ° C.) represented by the line c is determined as 300° C. in consideration for heat resistance of a semiconductor element. It is hence apparent from FIG. 1 that 185° C. is the heat treatment temperature (T in ° C.) at which the effect of improving reliability is found for the upper limit of the heat treatment time (t in minutes) that is 180 minutes. Thus, this temperature (185° C.) shall be the substantial lower limit of the heat treatment temperature (T in ° C.). With regard to the lower limit of the heat treatment time (t in minutes), it is apparent from FIG. 1 that the treatment for the heat treatment time of 0.47 minute shows the effect of improving reliability at the heat treatment temperature (T in ° C.) of 300° C. Thus, this time (0.47 minute) shall be the substantial lower limit of the heat treatment time (t in minutes). Based on these facts, the substantial range of the conditions (x) is the region surrounded by the curve a (t=3.3×10⁻⁵ exp(2871/T)), the line b (t=180 minutes), and the line c (T=300° C.) (including the curve a, the line b and the line c), as shown in FIG. 1.

When productivity and effects necessary and sufficient for reliability are taken into consideration for the aforementioned conditions (x), examples of particularly preferable heat treatment conditions include a heat treatment at 300° C. for three minutes, a heat treatment at 275° C. for five minutes, and a heat treatment at 250° C. for 20 minutes.

A heating treatment is per formed on a semiconductor device sealed in resin under the aforementioned conditions (x). The heating treatment is performed, for example, in the following forms: (1) a heating treatment in a post mold cure (PMC) step (or an after-cure step) subsequent to the step of sealing the semiconductor device in resin shall be the heating treatment satisfying the aforementioned conditions (x), whereby the post mold cure (PMC) step is performed; (2) a heating treatment in a solder reflow step subsequent to the post mold cure (PMC) step shall be the heating treatment satisfying the aforementioned conditions (x), whereby the solder reflow step is performed; and (3) a heating treatment is performed by providing a heating treatment step under the aforementioned conditions (x), independently of the post mold cure (PMC) step and the solder reflow step subsequent to the post mold cure (PMC) step. It should be noted that the heating temperature in the typical post mold cure (PMC) step is low as compared with the aforementioned conditions (x) of the heating treatment according to the present invention, resulting in insufficient temperature. Also, the heating time in the typical solder reflow step is relatively short, resulting in insufficient time.

### EXAMPLES

Next, inventive examples of the present invention will be described in conjunction with comparative examples. It should be noted that the present invention is not limited to the inventive examples.

Prior to the inventive examples, components to be described below for use in the inventive examples were prepared.

### Epoxy Resin a1

Biphenyl type epoxy resin represented by the general formula (1) wherein X is a single bond, and R₁ to R₄ are all CH₃, and having an epoxy equivalent of 192 and a melting point of 105° C.

### Epoxy Resin a2

Triphenylmethane type polyfunctional epoxy resin having an epoxy equivalent of 169 and a melting point of 60° C.

### Phenolic Resin b1

Biphenyl aralkyl type phenolic resin having a hydroxyl equivalent of 203 and a softening point of 65° C.

### Phenolic Resin b2

Phenolic novolac resin having a hydroxyl equivalent of 104 and a softening point of 60° C.

### Phenolic Resin b3

Xylylene novolac type phenolic resin having a hydroxyl equivalent of 175 and a softening point of 72° C.

### Phenolic Resin b4

Triphenylmethane type phenolic resin having a hydroxyl equivalent of 103 and a softening point of 83° C.

### Phenolic Resin b5

Triphenylmethane type phenolic resin having a hydroxyl equivalent of 97 and a softening point of 111° C.

### Curing Accelerator c1

2-Phenyl-4-methyl-5-dihydroxymethylimidazole.

### Curing Accelerator c2

2,4-Diamino-6-[2′-undecyl imidazolyl-(1′)]-ethyl-s-triazine.

### Curing Accelerator c3

Tetraphenylphosphonium tetra-p-tolylborate.

### Inorganic Filler

Spherical fused silica powder having an average particle diameter of 13 μm.

### Pigment

Carbon black.

### Flame Retardant

Magnesium hydroxide.

### Silane Coupling Agent

3-Methacryloxypropyltrimethoxysilane.

### Mold Release Agent

Polyethylene oxide wax.

### Production of Epoxy Resin Composition

Components listed in Tables 1 and 2 below were prepared in proportions listed in Tables 1 and 2, and were sufficiently mixed together using a mixer. Thereafter, the mixture was melt-knead at 100° C. for two minutes by using a double-arm kneading machine. Next, this melt was cooled down, and was then crushed. This produced intended epoxy resin compositions a to l in powder form.

TABLE 1
(part by weight)

| | Epoxy Resin Composition | | | | | |
|---|---|---|---|---|---|---|
| | a | b | c | d | e | f |
| Epoxy Resin | 5.50 | 5.50 | 5.49 | 5.93 | 7.43 | 7.59 |
| a1 | | | | | | |
| Epoxy Resin | — | — | — | — | — | — |
| a2 | | | | | | |
| Phenolic | 3.80 | 3.80 | 5.81 | — | — | — |
| Resin b1 | | | | | | |
| Phenolic | 1.0 | 1.0 | — | — | — | — |
| Resin b2 | | | | | | |
| Phenolic | — | — | — | 5.40 | — | — |
| Resin b3 | | | | | | |
| Phenolic | — | — | — | — | 3.98 | — |
| Resin b4 | | | | | | |
| Phenolic | — | — | — | — | — | 3.85 |
| Resin b5 | | | | | | |
| Curing | 0.21 | — | 0.35 | 0.32 | 0.24 | 0.23 |
| Accelerator | | | | | | |
| c1 | | | | | | |
| Curing | — | 0.21 | — | — | — | — |
| Accelerator | | | | | | |
| c2 | | | | | | |
| Curing | — | — | — | — | — | — |
| Accelerator | | | | | | |
| c3 | | | | | | |
| Inorganic | 88.5 | 88.5 | 87.4 | 87.4 | 87.4 | 87.4 |
| Filler | | | | | | |
| Pigment | 0.50 | 0.50 | 0.50 | 0.50 | 0.50 | 0.50 |
| Flame | 0.10 | 0.10 | 0.10 | 0.10 | 0.10 | 0.10 |
| Retardant | | | | | | |
| Silane | 0.10 | 0.10 | 0.10 | 0.10 | 0.10 | 0.10 |
| Coupling | | | | | | |
| Agent | | | | | | |
| Mold | 0.30 | 0.30 | 0.30 | 0.30 | 0.30 | 0.25 |
| Release | | | | | | |
| Agent | | | | | | |

TABLE 2
(part by weight)

| | Epoxy Resin Composition | | | | | |
|---|---|---|---|---|---|---|
| | g | h | i | j | k | l |
| Epoxy Resin a1 | — | — | 5.49 | 5.93 | 7.43 | 7.59 |
| Epoxy Resin a2 | 5.24 | 5.24 | — | — | — | — |
| Phenolic | — | — | 5.81 | — | — | — |
| Resin b1 | | | | | | |
| Phenolic | — | — | — | — | — | — |
| Resin b2 | | | | | | |
| Phenolic | — | — | — | 5.40 | — | — |
| Resin b3 | | | | | | |
| Phenolic | — | — | — | — | 3.98 | — |
| Resin b4 | | | | | | |
| Phenolic | 6.29 | 6.29 | — | — | — | 3.85 |
| Resin b5 | | | | | | |
| Curing | 0.13 | — | — | — | — | — |
| Accelerator | | | | | | |
| c1 | | | | | | |
| Curing | — | — | — | — | — | — |
| Accelerator | | | | | | |
| c2 | | | | | | |
| Curing | — | 0.13 | 0.35 | 0.32 | 0.24 | 0.23 |
| Accelerator | | | | | | |
| c3 | | | | | | |
| Inorganic | 87.4 | 87.4 | 87.4 | 87.4 | 87.4 | 87.4 |
| Filler | | | | | | |
| Pigment | 0.50 | 0.50 | 0.50 | 0.50 | 0.50 | 0.50 |
| Flame | 0.10 | 0.10 | 0.10 | 0.10 | 0.10 | 0.10 |
| Retardant | | | | | | |
| Silane | 0.10 | 0.10 | 0.10 | 0.10 | 0.10 | 0.10 |
| Coupling | | | | | | |
| Agent | | | | | | |
| Mold | 0.30 | 0.30 | 0.30 | 0.30 | 0.30 | 0.25 |
| Release | | | | | | |
| Agent | | | | | | |

Measurements of gelation time and hot hardness of the epoxy resin compositions produced in the aforementioned manner were made in accordance with a method to be described below.

### Gelation Time

The length of time it took to melt each of the epoxy resin compositions on a hot plate at 175° C. into a gel was measured. In consideration for curability, appropriate gelation time is 60 seconds or less.

### Hot Hardness

Each of the epoxy resin compositions was molded at a mold temperature of 175° C. for curing time of 90 seconds. The value of Shore D hardness of the cured material measured using a Shore D hardness tester after a lapse of 10 seconds since the opening of the mold was defined as hot hardness. It can be said that the higher the value of hot hardness is, the better the curability is.

### Manufacture of Semiconductor Device

### Inventive Examples 1 to 12 and Comparative Examples 1 to 24

A semiconductor element was sealed in resin using each of the epoxy resin compositions by transfer molding (under conditions of molding at 175° C. for 90 seconds) with an automatic molding machine (CPS-40L) available from TOWA Corporation. Then, an after-cure process was performed at 175° C. for three hours. This produced a semiconductor device (LQFP-144 with dimensions of 20 mm×20 mm×1.4 mm (thick)). Subsequently, a heating treatment (including no treatment) was performed on the semiconductor device under conditions to be described below, whereby an intended semiconductor device was provided. The high-temperature high-humidity reliability and gold wire sweep of the provided semiconductor device were evaluated in accordance with a method to be described below.

For the evaluation of the high-temperature high-humidity reliability, products of the inventive examples were semiconductor devices obtained by using the epoxy resin compositions a to f and by performing heat treatments under the conditions (x) (at 250° C. for three minutes, and at 250° C. for 20 minutes). On the other hands, products of the comparative examples were as follows: products obtained by using the epoxy resin compositions a to f and by performing no heat treatment (Comparative Examples 1 to 6); semiconductor devices obtained by performing a heat treatment under conditions (at 250° C. for one minute) falling outside the range of the conditions (x) (Comparative Examples 7 to 12); products obtained by using the epoxy resin compositions g to l and by performing no heat treatment (Comparative Examples 13 to 18); and products obtained by using the epoxy resin compositions g to l and by performing a heat treatment under the conditions (x) according to the present invention (at 250° C. for 20 minutes) (Comparative Examples 19 to 24).

### Rate of Increase in High-Temperature High-Humidity Reliability Lifetime

A heat treatment (including no heat treatment) was performed on the produced semiconductor devices under the aforementioned conditions. The semiconductor devices provided after the treatment were subjected to a HAST (Highly Accelerated Steam and Temperature) test under environments of 130° C. and 85% RH. In the HAST test, the resistances of the semiconductor devices were measured at constant time intervals without any bias while the semiconductor devices were exposed to conditions of 130° C. and 85% RH. After the HAST test, the resistances were measured. As a result, when the rate of increase in the resistances was not less than 10%, it was judged that a break failure occurred. Then calculations were done to determine the degree to which the HAST treatment time during which the break failure occurred was increased after the heat treatment (including no heat treatment) under the aforementioned conditions as compared with that obtained be fore the heat treatment. For this calculation, specifically, the HAST treatment time during which the break failure occurred after the heat treatment was performed was divided by the HAST treatment time during which the break failure occurred prior to the heat treatment. The calculated value was evaluated as the rate of increase in high-temperature high-humidity reliability lifetime.

### Gold Wire Sweep

The product LQFP-144 (with dimensions of 20 mm×20 mm×1.4 mm (thick)) with gold wires (having a diameter of 23 μm and a length of 6 mm) attached thereto was molded in each of the epoxy resin compositions a to l with an automatic molding machine (CPS-40L) available from TOWA Corporation (at 175° C. for 90 seconds). Then, an after-cure process was performed at 175° C. for three hours. This produced a semiconductor device. Specifically, for the manufacture of the semiconductor device, a gold wire 2 was attached to the package frame of the product LQFP-144 having a die pad 1, as shown in FIG. 2. The product LQFP-144 with the gold wire 2 attached thereto was sealed in resin using each of the aforementioned epoxy resin compositions, whereby a package was produced. In FIG. 2, the reference numeral 3 designates a semiconductor chip, and 4 designates a lead pin. Then, the amount of gold wire sweep in the produced package was measured with a soft X-ray analyzer. For the measurement, ten gold wires were selected for each package, and the amount of sweep of the gold wire 2 from the front side was measured. The maximum value of the amount of sweep of the gold wire 2 was defined as the value (d in mm) of the amount of gold wire sweep for the package. Then, a gold wire sweep rate ((d/L)×100) was calculated where L was a distance (in mm) between the opposite ends of the gold wire 2. The gold wire sweep rate not less than 6% was evaluated as being “unacceptable” and indicated by a cross. The gold wire sweep rate not less than 4% and less than 6% was evaluated as being “relatively poor but acceptable” and indicated by a triangle. The gold wire sweep rate less than 4% was evaluated as being “good” and indicated by an open circle.

The results of evaluation were also shown in Tables 3 to 8 below.

TABLE 3
(Heat Treatment at 250° C. for 3 min.)

| | Inventive Example | | | | | |
|---|---|---|---|---|---|---|
| | 1 | 2 | 3 | 4 | 5 | 6 |
| Type of | a | b | c | d | e | f |
| Epoxy Resin | | | | | | |
| Composition | | | | | | |
| Gelation | 50 | 50 | 49 | 48 | 46 | 46 |
| Time | | | | | | |
| (Sec) | | | | | | |
| Hot Hardness | 80 | 80 | 81 | 83 | 85 | 87 |
| (Shore D | | | | | | |
| Hardness) | | | | | | |
| Rate of | 2.1 | 2.1 | 1.8 | 1.4 | 1.5 | 1.3 |
| Increase in | | | | | | |
| High-Temperature | | | | | | |
| High-Humidity | | | | | | |
| Reliability | | | | | | |
| Lifetime | | | | | | |
| (Times) | | | | | | |
| Gold | ∘ | ∘ | ∘ | ∘ | ∘ | ∘ |
| Wire | | | | | | |
| Sweep | | | | | | |

TABLE 4
(Heat Treatment at 250° C. for 20 min.)

Inventive Example

| | 7 | 8 | 9 | 10 | 11 | 12 |
|---|---|---|---|---|---|---|
| Type of | a | b | c | d | e | f |
| Epoxy Resin | | | | | | |
| Composition | | | | | | |
| Gelation | 50 | 50 | 49 | 48 | 46 | 46 |
| Time | | | | | | |
| (Sec) | | | | | | |
| Hot Hardness | 80 | 80 | 81 | 83 | 85 | 87 |
| (Shore D | | | | | | |
| Hardness) | | | | | | |
| Rate of | 40 | 40 | 20 | 5.6 | 7.9 | 3.9 |
| Increase in | | | | | | |
| High- | | | | | | |
| Temperature | | | | | | |
| High-Humidity | | | | | | |
| Reliability | | | | | | |
| Lifetime | | | | | | |
| (Times) | | | | | | |
| Gold | ∘ | ∘ | ∘ | ∘ | ∘ | ∘ |
| Wire | | | | | | |
| Sweep | | | | | | |

TABLE 5
(No Heat Treatment)

| | Comparative Example | | | | | |
|---|---|---|---|---|---|---|
| | 1 | 2 | 3 | 4 | 5 | 6 |
| Type of | a | b | c | d | e | f |
| Epoxy Resin | | | | | | |
| Composition | | | | | | |
| Gelation | 50 | 50 | 49 | 48 | 46 | 46 |
| Time | | | | | | |
| (Sec) | | | | | | |
| Hot Hardness | 80 | 80 | 81 | 83 | 85 | 87 |
| (Shore D | | | | | | |
| Hardness) | | | | | | |
| Rate of | 1.0 | 1.0 | 1.0 | 1.0 | 1.0 | 1.0 |
| Increase in | | | | | | |
| High-Temperature | | | | | | |
| High-Humidity | | | | | | |
| Reliability | | | | | | |
| Lifetime | | | | | | |
| (Times) | | | | | | |
| Gold | ∘ | ∘ | ∘ | ∘ | ∘ | ∘ |
| Wire | | | | | | |
| Sweep | | | | | | |

TABLE 6
(Heat Treatment at 250° C. for 1 min.)

| | Comparative Example | | | | | |
|---|---|---|---|---|---|---|
| | 7 | 8 | 9 | 10 | 11 | 12 |
| Type of | a | b | c | d | e | f |
| Epoxy Resin | | | | | | |
| Composition | | | | | | |
| Gelation | 50 | 50 | 49 | 48 | 46 | 46 |
| Time | | | | | | |
| (Sec) | | | | | | |
| Hot Hardness | 80 | 80 | 81 | 83 | 85 | 87 |
| (Shore D | | | | | | |
| Hardness) | | | | | | |
| Rate of | 1.1 | 1.1 | 1.0 | 1.0 | 1.0 | 1.0 |
| Increase in | | | | | | |
| High-Temperature | | | | | | |
| High-Humidity | | | | | | |
| Reliability | | | | | | |
| Lifetime | | | | | | |
| (Times) | | | | | | |
| Gold | ∘ | ∘ | ∘ | ∘ | ∘ | ∘ |
| Wire | | | | | | |
| Sweep | | | | | | |

TABLE 7
(No Heat Treatment)

| | Comparative Example | | | | | |
|---|---|---|---|---|---|---|
| | 13 | 14 | 15 | 16 | 17 | 18 |
| Type of | g | h | i | j | k | l |
| Epoxy Resin | | | | | | |
| Composition | | | | | | |
| Gelation | 33 | 30 | 47 | 46 | 44 | 44 |
| Time | | | | | | |
| (Sec) | | | | | | |
| Hot Hardness | 89 | 89 | 81 | 83 | 85 | 87 |
| (Shore D | | | | | | |
| Hardness) | | | | | | |
| Rate of | 1.0 | 1.0 | 1.0 | 1.0 | 1.0 | 1.0 |
| Increase in | | | | | | |
| High-Temperature | | | | | | |
| High-Humidity | | | | | | |
| Reliability | | | | | | |
| Lifetime | | | | | | |
| (Times) | | | | | | |
| Gold | x | x | Δ | x | x | x |
| Wire | | | | | | |
| Sweep | | | | | | |

TABLE 8
(Heat Treatment at 250° C. for 20 min.)

| | Comparative Example | | | | | |
|---|---|---|---|---|---|---|
| | 19 | 20 | 21 | 22 | 23 | 24 |
| Type of | g | h | i | j | k | l |
| Epoxy Resin | | | | | | |
| Composition | | | | | | |
| Gelation | 33 | 30 | 47 | 46 | 44 | 44 |
| Time | | | | | | |
| (Sec) | | | | | | |
| Hot Hardness | 89 | 89 | 81 | 83 | 85 | 87 |
| (Shore D | | | | | | |
| Hardness) | | | | | | |
| Rate of | 6.0 | 3.0 | 1.1 | 1.0 | 1.2 | 1.0 |
| Increase in | | | | | | |
| High-Temperature | | | | | | |
| High-Humidity | | | | | | |
| Reliability | | | | | | |
| Lifetime | | | | | | |
| (Times) | | | | | | |
| Gold | x | x | Δ | x | x | x |
| Wire | | | | | | |
| Sweep | | | | | | |

The aforementioned results show that the products of the inventive examples which are sealed in resin using the epoxy resin compositions composed of specific compounding ingredients and which are subjected to the heating treatment under the specific conditions (x) produce good results in fluidity and curability and provide semiconductor devices high in the rate of increase in reliability lifetime and excellent in gold wire sweep evaluation and in reliability.

Further, semiconductor devices were manufactured when the heating treatment conditions after the resin sealing were 300° C. and three minutes and when they were 275° C. and five minutes. Measurement and evaluation similar to those described above were performed on these semiconductor devices. As a result, good measurement and evaluation similar to those described above were obtained, whereby the semiconductor devices excellent in reliability were provided.

On the other hand, the products of the comparative examples which were subjected to no heating treatment (no heat treatment) after the resin sealing, which were sealed in resin using epoxy resin compositions free of the specific epoxy resin or the amine-based curing accelerator and then subjected to the heating treatment, or which were subjected to the heating treatment under conditions falling outside the range of the conditions (x) were low in the rate of increase in high-temperature high-humidity reliability or poor in wire sweep evaluation.

A semiconductor device obtained by a method of manufacturing a semiconductor device has excellent high-temperature high-humidity reliability which has been unattainable using conventional sealing materials. The manufacturing method is therefore useful in the manufacture of various semiconductor devices.

Although a specific form of embodiment of the instant invention has been described above and illustrated in the accompanying drawings in order to be more clearly understood, the above description is made by way of example and not as a limitation to the scope of the instant invention. It is contemplated that various modifications apparent to one of ordinary skill in the art could be made without departing from the scope of the invention which is to be determined by the following claims.

What is claimed is:

1. A method of manufacturing a semiconductor device, comprising:
(a) sealing a semiconductor element in resin using a semiconductor-sealing epoxy resin composition; and
(b) performing a heating treatment after the step (a),
wherein the semiconductor-sealing epoxy resin composition comprises
(A) an epoxy resin represented by the following general formula (1): 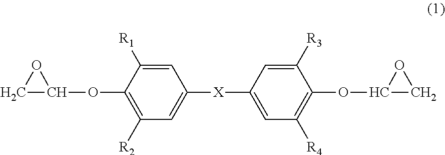
wherein X is a single bond, —CH₂—, —S— or —O—; and R₁ to R₄, which may be the same as or different from each other, are each —H or —CH₃,
(B) a phenolic resin,
(C) an amine-based curing accelerator, and
(D) an inorganic filler,
wherein the heating treatment in step (b) is performed under the following conditions:
(x) heat treatment conditions defined by a region in which a relationship t≧3.3×10⁻⁵ exp(2871/T) is satisfied where t is heat treatment time in minutes and T is heat treatment temperature in ° C. and where 185≦T≦300.

2. The method according to claim 1, wherein the content of the amine-based curing accelerator as the component (C) is in the range of 1 to 20 parts by weight per 100 parts by weight of the phenolic resin as the component (B).

3. The method according to claim 1, wherein the amine-based curing accelerator as the component (C) is an imidazole compound represented by the following general formula (2): 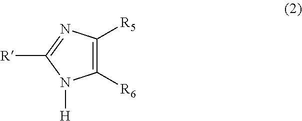
wherein R′ is an alkyl group or an aryl group; and R₅ and R₆, which may be the same as or different from each other, are each —CH₃ or —CH₂OH, and at least one of R₅ and R₆ is —CH₂OH.

4. The method according to claim 2, wherein the amine-based curing accelerator as the component (C) is an imidazole compound represented by the following general formula (2): 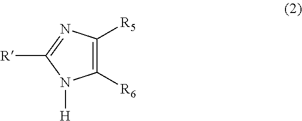
wherein R′ is an alkyl group or an aryl group; and R₅ and R₆, which may be the same as or different from each other, are each —CH₃ or —CH₂OH, and at least one of R₅ and R₆ is —CH₂OH.
